(19) United States
(12) Patent Application Publication
(10) Pub. No.: US 2017/0243788 A1
(43) Pub. Date: Aug. 24, 2017

(54) LAYOUT STRUCTURE FOR SEMICONDUCTOR INTEGRATED CIRCUIT

(71) Applicant: SOCIONEXT INC., Kanagawa (JP)

(72) Inventor: Hiroyuki SHIMBO, Kyoto (JP)

(21) Appl. No.: 15/590,201

(22) Filed: May 9, 2017

Related U.S. Application Data
(63) Continuation of application No. PCT/JP2015/005012, filed on Oct. 1, 2015.

(30) Foreign Application Priority Data
Nov. 19, 2014 (JP) 2014-234589

(51) Int. Cl. H01L 21/82; H01L 29/786; H01L 27/04; H01L 27/092; H01L 21/822; H01L 21/8238

(52) U.S. Cl. CPC H01L 21/82; H01L 21/822; H01L 21/8238; H01L 27/04; H01L 27/092; H01L 29/786

(57) ABSTRACT

Disclosed herein is a technique for providing a layout structure for a semiconductor integrated circuit with SOI transistors with an antenna error that could occur in a buried insulator under a source or drain taken into account. A standard cell, which is at least one of a plurality of standard cells that form the semiconductor integrated circuit, includes a signal interconnect serving as an output node to output a signal to outside of the standard cell, and an antenna diode formed between the signal interconnect and a substrate or a

### CROSS-REFERENCE TO RELATED APPLICATION

This is a continuation of International Application No. PCT/JP2015/005012 filed on Oct. 1, 2015, which claims priority to Japanese Patent Application No. 2014-234589 filed on Nov. 19, 2014, The entire disclosures of these applications are hereby incorporated by reference.

### BACKGROUND

The present disclosure relates to a layout structure for a semiconductor integrated circuit including transistors with a silicon-on-insulator (SOI) structure (hereinafter referred to as “SOI transistors”).

FIG. 7 is a cross-sectional view illustrating a configuration for an SOI transistor. As shown in FIG. 7, the SOI transistor includes a buried insulator (typically a buried oxide) 41 in a substrate or a well, a silicon thin film 42 formed on the buried insulator 41, and a transistor device comprised of a gate G, a source S, and a drain D on the silicon thin film 42. This structure tends to intensify an electric field generated in a channel region between the source and drain, thus contributing to the performance enhancement of the transistor. Note that a type of SOI structure having so thin a silicon film 42 as to fully deplete the channel region is called a fully-depleted silicon-on-insulator (FD-SOI).

Meanwhile, a semiconductor device manufacturing process may sometimes cause a so-called “antenna error.” The antenna error refers to a phenomenon that a transistor's gate dielectric under its gate electrode suffers either breakdown or damage due to the influx, into the gate electrode, of electric charges generated by plasma in the ambient during the manufacturing process of the transistor and collected in the metal wires of the transistor that are electrically connected to the gate electrode. In the case of an SOI transistor, the possibility of such antenna errors' occurring in not only the gate dielectric but also the buried insulator under the source or drain needs to be taken into account. The reason is that those electric charges collected in the metal wires of the transistor being manufactured also flow into the source or drain electrically connected to the metal wires to cause breakdown or damage to the buried insulator under a doped layer serving as the source or drain.

Thus, in order to avoid causing such antenna errors in an SOI transistor, Japanese Unexamined Patent Publication No. 2003-133559 discloses a technique for inserting an antenna diode for channeling those electric charges into the substrate.

Japanese Unexamined Patent Publication No. 2003-133559, however, fails to disclose actually how to insert such an antenna diode into a semiconductor integrated circuit including SOI transistors.

The present disclosure provides a layout structure for a semiconductor integrated circuit including SOI transistors with such antenna errors that could occur in the buried insulator under the source or drain taken into account.

### SUMMARY

An aspect of the present disclosure provides a layout structure for a semiconductor integrated circuit including silicon-on-insulator (SOI) transistors. The structure includes a plurality of standard cells, each including a circuit comprised of the SOI transistors. A first standard cell, which is at least one of the plurality of standard cells, includes: a first signal interconnect serving as an output node through which a signal is output to outside of the first standard cell; and a first antenna diode formed between the first signal interconnect and a substrate or a well.

According to this aspect, a first standard cell, which is at least one of a plurality of standard cells forming a semiconductor integrated circuit, includes: a first signal interconnect serving as an output node through which a signal is output to outside of the first standard cell; and a first antenna diode formed between the first signal interconnect and a substrate or a well. Using this first standard cell eliminates antenna errors from a buried insulator under a doped layer of an SOI transistor connected to the output node. This significantly reduces the need for separately inserting an antenna diode during the physical design process of a semiconductor integrated circuit, and therefore, cuts down the number of physical design process steps involved with the insertion of the antenna diode.

The present disclosure provides a technique for avoiding causing antenna errors without prolonging the design turnaround time (TAT) for a semiconductor integrated circuit including SOI transistors.

### BRIEF DESCRIPTION OF THE DRAWINGS

FIG. 1A is a plan view illustrating an exemplary layout structure for a standard cell according to an embodiment, and FIG. 1B is a circuit diagram of the standard cell.

FIG. 2 is a cross-sectional view of the layout structure shown in FIG. 1A.

FIG. 3A is a plan view illustrating another exemplary layout structure for a standard cell according to another embodiment, and FIG. 3B is a circuit diagram of the standard cell.

FIG. 4 is a plan view illustrating still another exemplary layout structure for a standard cell according to still another embodiment.

FIG. 5 illustrates an exemplary layout of signal interconnects between multiple standard cells according to an embodiment.

FIGS. 6A and 6B illustrate antenna errors that could occur in the structure shown in FIG. 5, wherein FIG. 6A illustrates an antenna error occurring in a gate oxide of input-end standard cells, and FIG. 6B illustrates an antenna error occurring in a buried insulator of an output-end standard cell.

FIG. 7 is a cross-sectional view illustrating an SOI transistor.

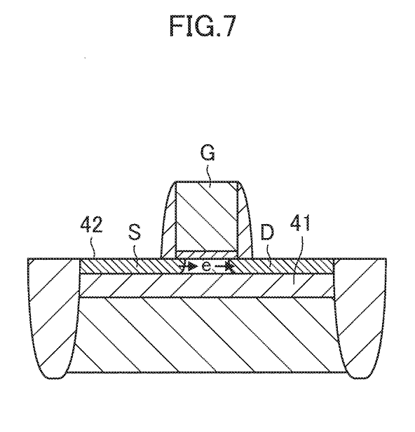

### DETAILED DESCRIPTION

Embodiments of the present disclosure will now be described with reference to the accompanying drawings.

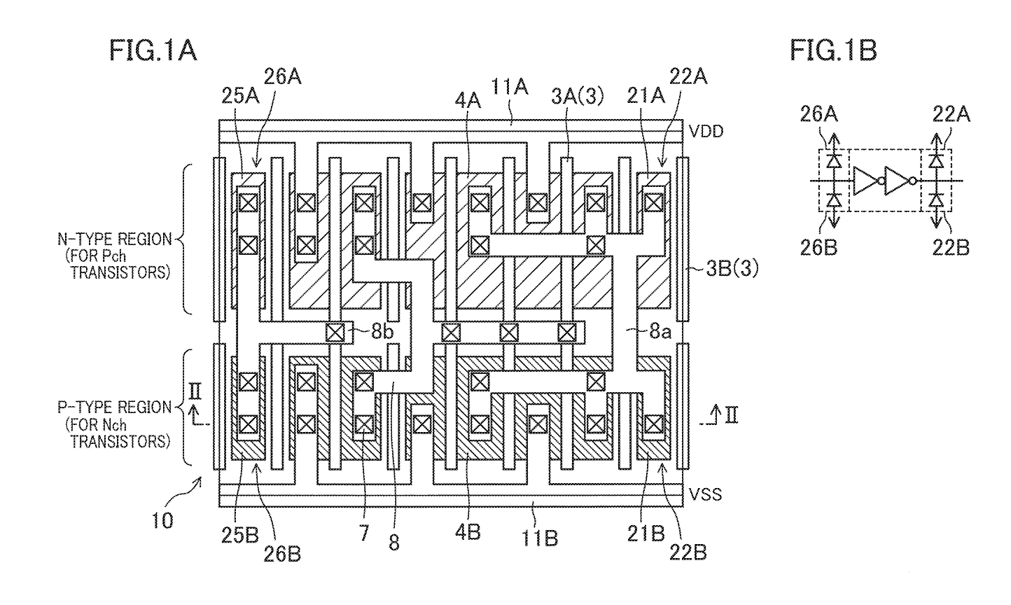

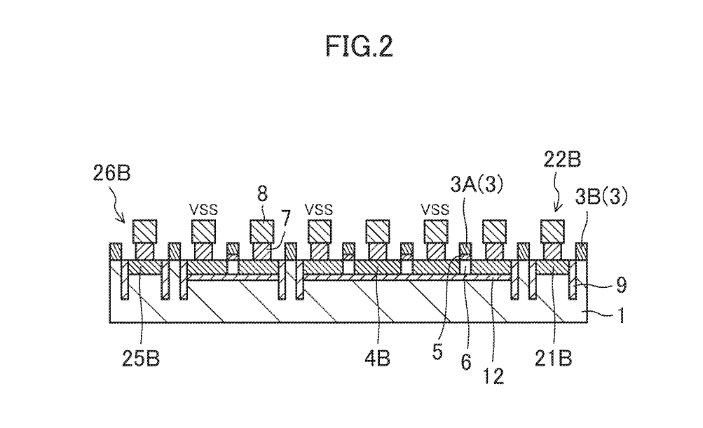

FIG. 1A is a plan view illustrating an exemplary layout structure for a standard cell according to an embodiment, and FIG. 1B is a circuit diagram of the standard cell shown in FIG. 1A. FIG. 2 is a cross-sectional view taken along the plane II-II shown in FIG. 1A. The standard cell 10 shown in FIG. 1A, serving as a first standard cell, may be implemented as a circuit in which two inverters are connected together in series as shown in FIG. 1B. The transistors included in the standard cell 10 have the SOI structure described above. In the standard cell 10, antenna diodes 22A, 22B are connected to an output node, and antenna diodes 26A, 26B are connected to an input node. Arranging a plurality of standard cells, including this standard cell 10, may form a circuit block in a semiconductor integrated circuit.

In FIG. 1A, an N-type region where P-channel transistors are formed and a P-type region where N-channel transistors are formed are defined between a power supply line 11A for supplying a supply potential VDD and a power supply line 11B for supplying a ground potential VSS. The standard cell 10 is vertically divided into the N-type and P-type regions in FIG. 1A. In this embodiment, an N-well functioning as the N-type region is supposed to be defined over a P-type substrate functioning as the P-type region.

A P-type doped layer 4A forming part of transistors is defined in the N-type region. An N-type doped layer 4B forming part of transistors is defined in the P-type region. Gates are identified by the reference numeral 3 and may be made of poly silicon, for example. The gates 3 include gates 3A, each of which forms part of a transistor, and dummy gates 3B, none of which forms any transistors. Signal interconnects 8 are arranged as metal wires over, and electrically connected via contacts 7 to, the doped layer 4A, 4B and the gates 3.

As shown in FIG. 2, in the P-type region, a buried oxide 12, an exemplary buried insulator, is provided in the P-type substrate 1, and the N-type doped layer 4B has been formed on the buried oxide 12. Although not shown in FIG. 2, in the N-type region, a buried oxide has been formed in an N-well, and the P-type doped layer 4A has been formed on the buried oxide. A gate oxide 5 has been formed as an exemplary gate dielectric under the gate 3A of each transistor, and a channel region 6 has been defined under the gate oxide 5. A portion of the doped layer 4A, 4B is connected to the signal interconnects 8 via the contacts 7. The reference numeral 9 denotes shallow trench isolations (STIs).

The signal interconnects 8 in the standard cell 10 include a signal interconnect 8a serving as a first signal interconnect to be an output node for outputting a signal to outside of the standard cell 10, and a signal interconnect 8b serving as a second signal interconnect to be an input node for inputting a signal from outside of the standard cell 10. In addition, in this standard cell 10, a P-type doped layer 21A, 25A and an N-type doped layer 21B, 25B are further provided separately from the doped layer 4A, 4B forming parts of transistors. The P-type doped layer 21A, 25A is provided right over the N-well with no buried oxide interposed between them. The N-type doped layer 21B, 25B is provided right on the P-type substrate 1 with no buried oxide 12 interposed between them. The signal interconnect 8a is electrically connected to the P-type doped layer 21A and the N-type doped layer 21B, thus forming antenna diodes 22A, 22B (as first antenna diodes) between the signal interconnect 8a and the substrate or well The signal interconnect 8b is electrically connected to the P-type doped layer 25A and the N-type doped layer 25B, thus forming antenna diodes 26A, 26B (as second antenna diodes) between the signal interconnect 8b and the substrate or well.

Now, it will be described what significance the use of the standard cell 10 shown in FIGS. 1 and 2 has according to the present disclosure.

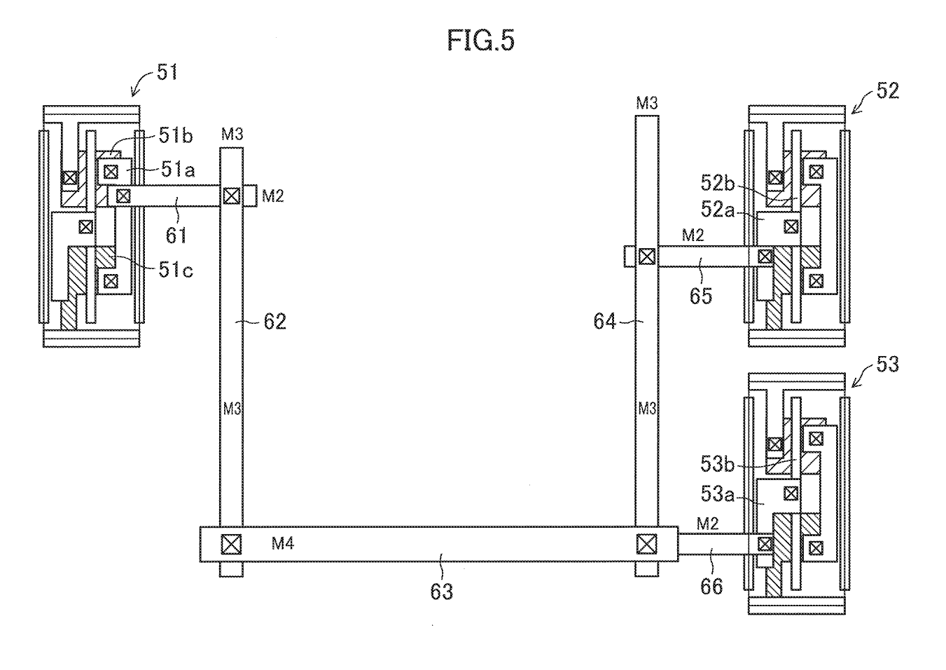

FIG. 5 illustrates an exemplary layout of signal interconnects between multiple standard cells. In FIG. 5, a signal is output from a standard cell 51 on the transmitting end (i.e., on the output end) to standard cells 52, 53 on the receiving end (i.e., on the input end). The output signal of the standard cell 51 is transmitted from an M1 interconnect 51a, serving as an output node for the standard cell 51, to M1 interconnects 52a, 53a, serving as input nodes for the standard cells 52, 53, respectively, through an M2 interconnect 61, an M3 interconnect 62, an M4 interconnect 63, another M3 interconnect 64, and two more M2 interconnects 65, 66. Note that M1, M2, M3, and M4 denote the respective levels of multi-level metal interconnects. Specifically, these ordinal numbers indicate that the larger the ordinal number M1, M2, M3, or M4 of a given metal interconnect is, the higher the level of the metal interconnect is. When an SOT transistor is used, there is a buried insulator under the doped layer 51b, 51c that is electrically connected to the M1 interconnect 51a in the standard cell 51.

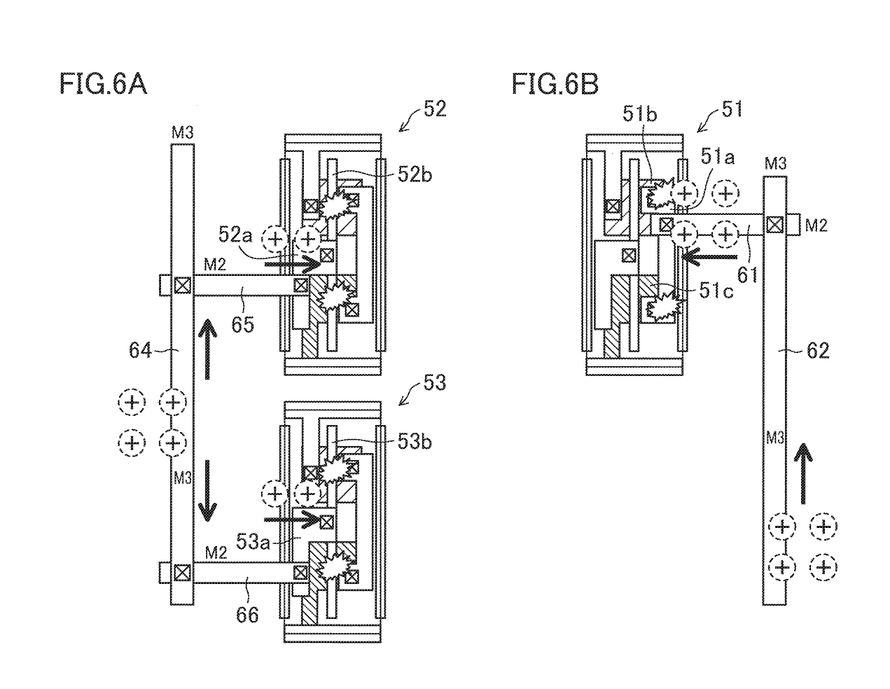

FIGS. 6A and 6B illustrate antenna errors that could occur in the signal interconnects shown in FIG. 5, wherein FIG. 6A illustrates an antenna error occurring in a gate oxide of input-end standard cells, and FIG. 6B illustrates an antenna error occurring in a buried insulator of an output-end standard cell. In a semiconductor integrated circuit comprised of conventional transistors with a so-called “bulk structure,” only the possibility of antenna errors' occurring in their gate dielectric needs to be taken into account. Specifically, as for the signal interconnects shown in FIG. 5, antenna inspection for any possible antenna errors needs to be carried out on just the gate dielectric under the gate lines 52b, 53b in the standard cells 52, 53 shown in FIG. 6A. In the case of using SOI transistors, however, antenna errors could also occur in the buried insulator under the doped layer 51b, 51c of the standard cell 51 as shown in FIG. 6B. Therefore, the buried insulator also needs to be subjected to the antenna inspection, thus requiring inserting a far greater number of antenna diodes than in a situation where transistors with the bulk structure are used. Consequently, the insertion of the huge number of antenna diodes would necessitate rerouting, and would cause a deterioration of timing characteristics, and/or a non-negligible increase in the overall circuit area. This could lead to a significant increase in the design TAT of the semiconductor integrated circuit.

In contrast, in the standard cell 10 shown in FIG, 1, antenna diodes 22A, 22B are provided for the signal interconnect 8a serving as an output node. In performing a physical design process of a semiconductor integrated circuit, using a standard cell such as the standard cell 10 automatically provides antenna diodes for a signal interconnect to be the output node of the standard cell, thus allowing for avoiding causing antenna errors such as the ones shown in FIG. 6B. This significantly decreases the need for separately inserting antenna diodes. Consequently, a variation in wiring load capacitance involved with the insertion of antenna diodes, and an increase in propagation delay and/or a deterioration in timing characteristics resulting from such a variation may all be reduced. In addition, the time and trouble for relocating already placed cells due to the insertion of additional antenna cells and the deterioration to be caused in timing characteristics by this relocating may be cut down as well. As a result, the design TAT of a semiconductor integrated circuit may be significantly shortened.

Furthermore, in the standard cell 10 shown in FIG. 1, antenna diodes 26A, 26B are provided for the signal interconnect 8b serving as an input node. In performing a physical design process of a semiconductor integrated circuit, using a standard cell such as the standard cell 10 automatically provides antenna diodes for a signal interconnect to be the input node of the standard cell, thus allowing for avoiding causing antenna errors such as the ones shown in FIG. 6A. This significantly decreases the need for separately inserting antenna diodes.

In the configuration shown in FIGS. 1A and 1B, the input-node antenna diodes 26A and 26B are not essential ones for the present disclosure but may be omitted. Furthermore, in the configuration shown in FIG. 1A, output-node antenna diodes 22A and 22B are arranged in both of the N-type and P-type regions. However, only one of these two output-node antenna. diodes 22A, 22B may be placed in either the N-type region or the P-type region.

### FIRST ALTERNATIVE EMBODIMENT

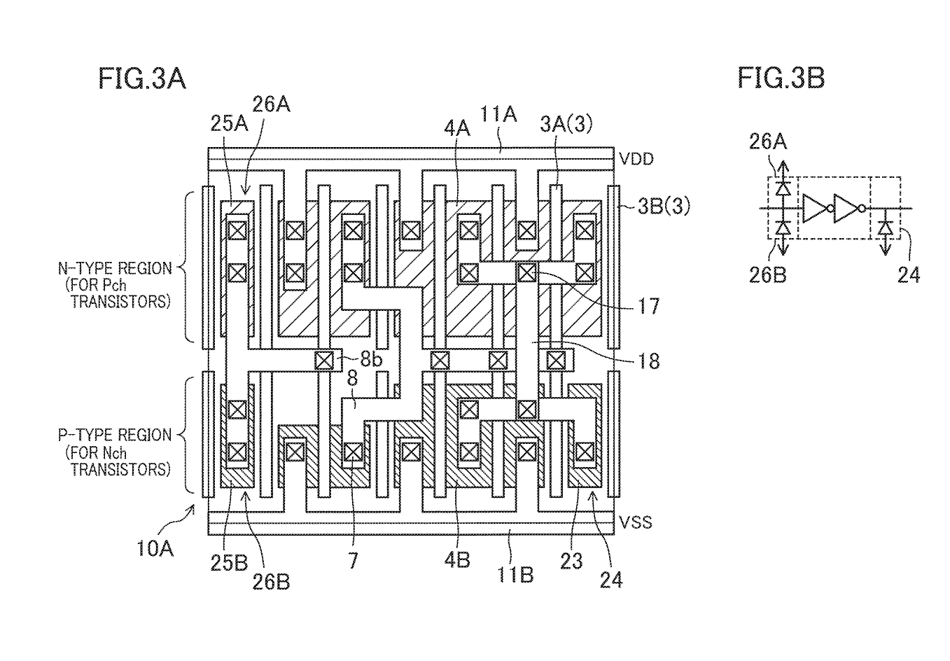

FIG. 3A is a plan view illustrating another exemplary layout structure for a standard cell according to another embodiment, and FIG. 3B is a circuit diagram of the standard cell shown in FIG. 3A. In FIGS. 3A and 3B, any component also shown in FIGS. 1A and 1B and having substantially the same function as its counterpart shown in FIGS. 1A and 1B is identified by the same reference numeral as the counterpart's, and a detailed description thereof will be omitted herein to avoid redundancies. The standard cell 10A shown in FIG. 3A, serving as a first standard cell, may be implemented as a circuit in which two inverters are connected together in series as shown in FIG. 3B. The transistors included in the standard cell 10A have the SOI structure described above. In the standard cell 10A, an antenna diode 24 is connected to an output node, and antenna diodes 26A, 26B are connected to an input node. Arranging a plurality of standard cells, including this standard cell 10A, may form a circuit block in a semiconductor integrated circuit.

In FIG. 3A, an N-type region where P-channel transistors are formed and a P-type region where N-channel transistors are formed are defined between a power supply line 11A for supplying a supply potential VDD and a power supply line 11B for supplying a ground potential VSS. The standard cell 10A is vertically divided into the N-type and P-type regions in FIG. 3A. In this embodiment, an N-well functioning as the N-type region is supposed to be defined over a P-type substrate functioning as the P-type region.

A P-type doped layer 4A forming part of transistors is defined in the N-type region. An N-type doped layer 4B forming part of transistors is defined in the P-type region. Signal interconnects 8 made of a metal are arranged over, and are electrically connected via contacts 7 to, the doped layer 4A, 4B and gates 3. Another signal interconnect 18 serving as a first signal interconnect to be an output node through which a signal is output to outside of the standard cell 10A is further arranged over the signal interconnects 8. The signal interconnect 18 is connected to the signal interconnects 8 through vias 17.

In addition, in this standard cell 10A, a P-type doped layer 25A and an N-type doped layer 23, 25B are further provided separately from the doped layer 4A, 4B forming parts of transistors. The P-type doped layer 25A is provided right on the N-well with no buried insulator interposed between them. The N-type doped layer 23, 25B is provided right on the P-type substrate 1 with no buried insulator interposed between them. The signal interconnect 18 is electrically connected to the N-type doped layer 23, thus forming an antenna diode 24 (as a first antenna diode) between the signal interconnect 18 and the substrate or well. The signal interconnect 8b is electrically connected to the P-type doped layer 25A and the N-type doped layer 25B, thus forming antenna diodes 26A, 26B (as second antenna diodes) between the signal interconnect 8b and the substrate or well.

In the standard cell 10A shown in FIG. 3A, the antenna diode 24 arranged in the P-type region is connected to the signal interconnect 18 serving as an output node. However, no antenna diodes are provided at a position in the N-type region vertically (corresponding to the first direction) opposite to the antenna diode 24, but the doped region 4A forming parts of the transistors is arranged. A standard cell in which the number of gates of P-channel transistors performing a logical function is different from that of gates of N-channel transistors performing the same function may sometimes have a vacant P-type or N-type region. Arranging an antenna diode in such a vacant region provides a layout such as the one shown in FIG. 3A, which leads to a further reduction in the area of a standard cell including an output-node antenna diode.

In the configuration shown in FIG. 3A, the input-node antenna diodes 26A and 2613 are not essential ones for the present disclosure but may be omitted. Optionally, contrary to the exemplary configuration shown in FIG. 3A, an output-node antenna diode may be arranged in the N-type region, and a doped region forming parts of transistors may be provided at a position in the P-type region vertically opposite to the output-node antenna diode.

### SECOND ALTERNATIVE EMBODIMENT

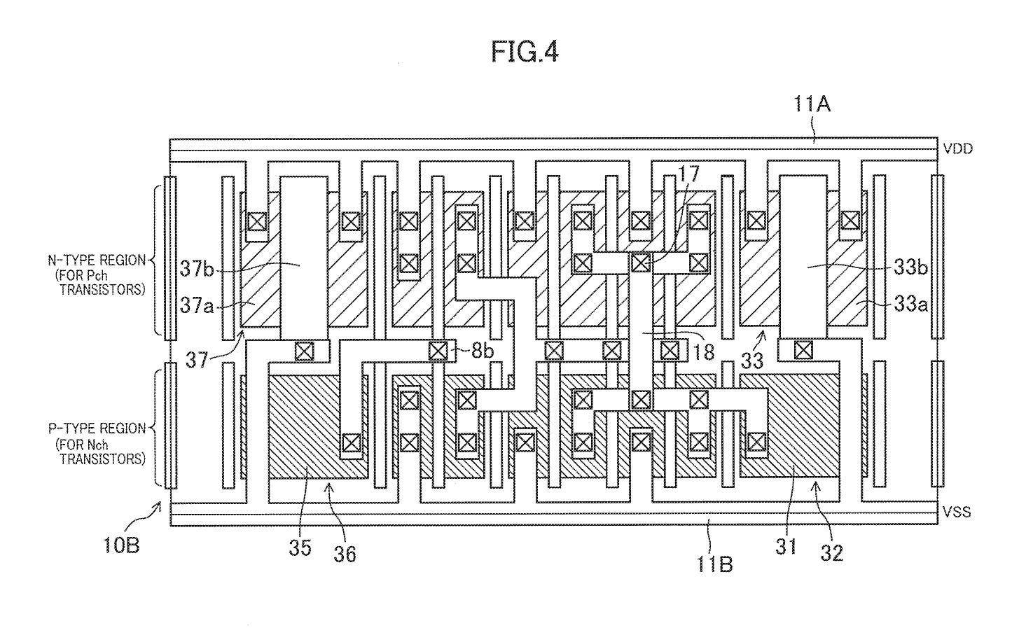

FIG. 4 is a plan view illustrating still another exemplary layout structure for a standard cell according to still another embodiment. In FIG, 4, any component also shown in FIGS. 3A and 3B and having substantially the same function as its counterpart shown in FIGS. 3A and 3B is identified by the same reference numeral as the counterpart's, and a detailed description thereof will be omitted herein to avoid redundancies.

In FIG. 4, an N-type region where P-channel transistors are formed and a P-type region where N-channel transistors are formed are defined between a power supply line 11A for supplying a supply potential VDD and a power supply line 11B for supplying a ground potential VSS. The standard cell 10B shown in FIG. 4, serving as a first standard cell, is vertically divided into the N-type and P-type regions in FIG. 4. In this embodiment, an N-well functioning as the N-type region is supposed to be defined on a P-type substrate functioning as the P-type region. In the standard cell 10B, antenna diodes 32, 36 are formed in the P-type region, and capacitors 33, 37 are formed in the N-type region.

That is to say, an N-type doped layer 31, 35 is provided in the P-type region. The N-type doped layer 31 is electrically connected to a signal interconnect 18 to be an output node, thus forming an antenna diode (first antenna diode) 32 between the signal interconnect 18 and the substrate or well. The N-type doped layer 35 is electrically connected to a signal interconnect 8b to be an input node, thus forming an antenna diode (second antenna diode) 36 between the signal interconnect 8b and the substrate or well. Meanwhile, a P-type doped layer 33a, 37a is provided in the N-type region, and gate lines 33b, 37h with a broad line width are arranged over the P-type doped layer 33a, 37a. The P-type doped layer 33a, 37a is connected to one power supply line 11A. The gate lines 33b, 37b are connected to the other power supply line 11B. Thus, capacitors 33 and 37 are formed between the power supply line 11A for supplying a supply potential VDD and the power supply line 11B for supplying a ground potential VSS.

In the standard cell 10B shown in FIG. 4, antenna diodes 32, 36 are formed in the P-type region, and capacitors 33 and 37 are arranged at respective positions in the N-type region vertically (corresponding to the first direction) opposite to the antenna diodes 32, 36, respectively. This configuration may further reduce the area of a standard cell including an output-node antenna diode and capacitors.

In the configuration shown in FIG. 4, the input-node antenna diode 36 is not an essential one for the present disclosure but may be omitted. Optionally, contrary to the exemplary configuration shown in FIG. 4, an output-node antenna diode may be arranged in the N-type region and a capacitor may be arranged at a position in the P-type region vertically opposite to the output-node antenna diode.

A standard cell including such an output-node antenna diode may be used as a constituent for a clock signal transmitter circuit in a semiconductor integrated circuit, for example, or may also be used as a constituent for a circuit for transmitting a signal between multiple circuit blocks.

In general, a clock signal transmitter circuit tends to have a long wire length between buffers that form the circuit. The longer the wire length is, the more likely an antenna error occurs. That is why using a standard cell with an output-node antenna diode such as the one exemplified in the foregoing description of the present disclosure as buffers for a clock signal transmitter circuit leads to avoiding causing antenna errors. Likewise, a circuit for transmitting a signal between multiple circuit blocks also tends to have an extended wire length. Thus, using a standard cell with an output-node antenna diode such as the one exemplified in the foregoing description of the present disclosure leads to eliminating antenna errors.

A semiconductor integrated circuit with SOI transistors according present disclosure may avoid causing antenna errors without prolonging the design TAT, and therefore, contributes effectively to enhancing the yield of very-large-scale integrated circuits (VLSIs), for example.

What is claimed is:

1. A layout structure for a semiconductor integrated circuit including silicon-on-insulator (SOI) transistors, the structure comprising
a plurality of standard cells, each including a circuit comprised of the SOI transistors, wherein
a first standard cell, which is at least one of the plurality of standard cells, includes:
a first signal interconnect serving as an output node through which a signal is output to outside of the first standard cell; and
a first antenna diode formed between the first signal interconnect and a substrate or a well.

2. The layout structure of claim 1, wherein
the first standard cell includes:
a second signal interconnect serving as an input node through which a signal is input from outside of the first standard cell; and
a second antenna diode formed between the second signal interconnect and the substrate or the well.

3. The layout structure of claim 1, wherein
the first standard cell is divided into an N-type region and a P-type region in a first direction, and
in the first standard cell, the first antenna diode is arranged in one of the N- and P-type regions, and a doped region forming parts of a transistor is arranged at a position in the other of the N- and P-type regions so as to be opposite to the first antenna diode in the first direction.

4. The layout structure of claim 1, wherein
the first standard cell is divided into an N-type region and a P-type region in a first direction, and
in the first standard cell, the first antenna diode is arranged in one of the N- and P-type regions, and a capacitor is arranged at a position in the other of the N- and P-type regions between a power supply line for supplying a supply potential and a power supply line for supplying a ground potential so as to be opposite to the first antenna diode in the first direction.

5. The layout structure of claim 1, wherein the first standard cell forms part of a circuit for transmitting a clock signal.

6. The layout structure of claim 1, wherein the first standard cell forms part of a circuit for transmitting a signal between multiple circuit blocks.
